(19) United States
(12) Patent Application Publication
(10) Pub. No.: US 2002/0106864 A1
(43) Pub. Date: Aug. 8, 2002

(54) METHOD FOR FILLING OF A SHALLOW TRENCH ISOLATION

(76) Inventors: Tai-Ju Chen, Tainan City (TW); Hua-Chou Tseng, Hsin-Chu City (TW)

Correspondence Address: POWELL, GOLDSTEIN, FRAZER & MURPHY LLP, P.O. BOX 97233, WASHINGTON, DC, 20090-7233, US

(21) Appl. No.: 09/779,074

(22) Filed: Feb. 8, 2001

(51) Int. Cl. H01L 21/76

(52) U.S. Cl. 438/424

(57) ABSTRACT

This invention relates to a method for filling of a shallow trench isolation, more particularly, to a method of gap filling shallow trench isolation with ozone-TEOS. A pad oxide layer is provided over the surface of a substrate. The first nitride layer is deposited overlying the pad oxide layer. A isolation trench is etched through the first nitride and pad oxide layers into the semiconductor substrate. A thermal oxide layer is grown within the isolation trenches. The second silicon nitride layer is deposited over the first nitride layer and over the thermal oxide layer within the isolation trenches. The second silicon nitride layer and the thermal oxide layer which are on the first surface of the isolation trenches are removed by using the anisotropic etching method and the semiconductor substrate is shown. Thereafter, an ozone-TEOS layer is deposited overlying the second silicon nitride layer and the semiconductor substrate and filling the isolation trenche. The ozone-TEOS layer is polished away stopping at the first nitride layer. This completes the formation of shallow trench isolation in the fabrication of the integrated circuit device.

### BACKGROUND OF THE INVENTION

1. Field of the Invention

This invention relates to a method for filling of a shallow trench isolation, more particularly, to a method of gap filling shallow trench isolation with ozone (O₃)-tetraethoxysilane (TEOS) in the fabrication of integrated circuits.

2. Description of the Prior Art

Shallow trench isolation (STI) has been gaining popularity for quarter-micron technology and beyond to replace the traditional localized oxidization of silicon (LOCOS) isolation process. However, as the design rule continues to shrink, gap filling of the smaller trench becomes a great challenge. Currently, both ozone-TEOS and high density plasma chemical vapor deposited (HDPCVD) oxide are being studied extensively for STI gap filling. For the ozone-TEOS approach, surface sensitivity of sub-atmospheric chemical vapor deposited (SACVD) ozone-TEOS oxide on thermal oxide is the most critical issue. An underlayer of thermal oxide is desired for good sidewall isolation. However, the surface sensitivity of ozone-TEOS deposition over thermal oxide results in a degradation of the ozone-TEOS deposition rate and wet etch rate. Therefore, a suitable interface must be formed over thermal oxide before ozone-TEOS is deposited.

Referring to FIG. 1, there is shown a substrate which comprises a semiconductor substrate 10, a pad oxide layer 12 and the first silicon nitride layer 14. The material of the semiconductor substrate 10 is monocrystalline silicon. Shallow trench isolation regions are to be formed in the semiconductor substrate to isolate active areas of the integrated circuit device from one another. A layer of pad oxide layer 12 is grown on the surface of the semiconductor substrate 10. Then the first silicon nitride layer 14 is deposited over the pad oxide layer. We usually use silicon dioxide to be the material of the pad oxide layer 12.

Referring to FIG. 2, a shallow trench is etched into the substrate using conventional photolithography and etching techniques. The shallow trenches 16 may be as small as 0.35 microns in width and are etched to a depth of between about 3000 and 5000 angstroms. A thermal oxide layer 17 is grown on the sidewalls of the trench 16 to a thickness of about 350 angstroms, as depicted in FIG. 3. This thermal oxide provides a good sidewall isolation. Then the trenches are to be filled with a dielectric material. The trenches will be filled with ozone-TEOS. First, an underlayer is to be deposited within the trenches to eliminate surface sensitivity and to eliminate the deleterious effects of the thermal oxide underlayer on ozone-TEOS deposition and wet etch rates.

Referring to FIG. 4, the second silicon nitride layer 18 is deposited on the thermal oxide layer 17 and the first silicon nitride layer 14. A layer of plasma-enhanced silane oxide SiH₄ 18 is deposited by plasma enhanced chemical vapor deposition (PECVD) over the surface of the substrate and within the trenches 16. Then nitrogen is implanted to the plasma-enhanced silane oxide layer by using plasma treatment and the plasma-enhanced silane oxide become the second silicon nitride layer 18. The second silicon nitride layer 18 can eliminate surface sensitivity and to eliminate the deleterious effects of the thermal oxide underlayer on ozone-TEOS deposition and wet etch rates.

Referring to FIG. 5, the ozone-TEOS layer 22 is deposited on the second silicon nitride layer 18 and is filled of the trench 16 by using the subatmospheric chemical vapor deposition method. Referring to FIG. 6, we remove the second silicon nitride 18 layer which is on both sides of the trench 16 and over deposition in ozone-TEOS 22 by using a polishing way. At present, the polishing way is chemical mechanical polishing (CMP). When we polish to the first silicon nitride, we stop the chemical mechanical polishing process and end the gap filling of shallow trench isolation process.

Referring to FIG. 7, when the ozone-TEOS layer 22 is deposited on the second silicon nitride layer 18 and is filled of the trench 16 by using the subatmospheric chemical vapor deposition method, the deposition velocity of ozone-TEOS in the first surface 24, the second surface 26 and the third surface 28 are the same. This condition can easily make that when ozone-TEOS which is deposited on the second surface 26 of the trench, and ozone-TEOS which is deposited on the third surface 28 of the trench are contact with each other and ozone-TEOS which is deposited on the first surface of the trench still not reach this contact point. The vapor of ozone-TEOS will not enter into the trench and will not be deposited on the first surface 24 of the trench continuously. The void defects 19 will be produced inside the ozone-TEOS layer 22 in the trench 16 and will be found hardly. The void defects 19 inside the trench 16 will make the semiconductor elements occur in leak of an electric current in the proceeding process. Especially when the volume of the semiconductor element is reduced and the size of the trench 16 is following more and more small, the void defects 19 will be produced more easily by using traditional method to fill of the shallow trench isolation. Therefore, we must use the present invention to reduce the probability of producing the void defects inside the trench. The bottom of the trench 16 is the first surface 24 of the trench and the sidewalls of the trench 16 comprises the second surface 26 and the third surface 28 of the trench 16.

### SUMMARY OF THE INVENTION

In accordance with the above-mentioned invention backgrounds, the void defects are produced inside the filled layer of the trench more easily by using traditional method. The main objective of the invention is to provide a method for filling the shallow trench isolation by ozone-TEOS and preventing the void defects to be produced inside the ozone-TEOS layer in the integrated circuit process.

The second objective of this invention is to prevent the void defects to be produced inside the shallow trench isolation and increase the velocity of the process by using different reaction rate in silicon to ozone-TEOS and silicon nitride to ozone-TEOS.

The third objective of this invention is to improve the structure strength of the deposited ozone-TEOS layer by using the second silicon nitride layer which is deposited on the thermal oxide layer.

The fourth objective of this invention is to prevent the void defects which are produced inside the filled layer of the trench to decrease the volume of the semiconductor elements successfully and increase the density of the elements in the semiconductor.

The further objective of this invention is to reduce the probability of leaking the electric current in the semiconductor element and to increase the qualities of the semiconductor elements by avoiding the void defects being produced inside the filled layer of the trench.

In according to the foregoing objectives, the present invention provides a method for using ozone-TEOS to be the material to fill of the trench and to avoid the void defects being produced inside the filled layer of the trench by using different reaction rate in silicon to ozone-TEOS and silicon nitride to ozone-TEOS. The void defects will affect the semiconductor elements to occur leaking the electric current. This method can increase the qualities of the semiconductor elements and decrease the volume of the semiconductor elements successfully to increase the density of the elements in the semiconductor. The method can also increase the process velocity of filling of the shallow trench isolation.

### BRIEF DESCRIPTION OF THE DRAWINGS

In the accompanying drawing forming a material part of this description, there is shown:

FIG. 1 is a cross-section representation of a substrate;

FIG. 2 is a cross-section representation of forming a trench in the substrate;

FIG. 3 is a cross-section representation of forming a thermal oxide layer on the surface of the trench;

FIG. 4 is a cross-section representation of depositing the second silicon nitride layer on the thermal oxide layer which is on the surface of the trench and the first silicon nitride layer which is formed on the substrate.

FIG. 5 is a cross-section representation of depositing the ozone-TEOS layer on the second silicon nitride layer, filling the trench, and producing the void defects inside the trench.

FIG. 6 is a representation of substrate after using the chemical mechanical polishing method to remove the over deposited ozone-TEOS.

FIG. 7 is a representation of producing the void defects inside the filled trench by using the traditional method.

FIG. 8 is a cross-section representation of a substrate;

FIG. 9 is a cross-section representation of forming a trench in the substrate;

FIG. 10 is a cross-section representation of forming a thermal oxide layer on the surface of the trench;

FIG. 11 is a cross-section representation of depositing the second silicon nitride layer on the thermal oxide layer which is on the surface of the trench and the first silicon nitride layer which is formed on the substrate.

FIG. 12 is a cross-section representation of removing the second silicon nitride layer and the thermal oxide layer which are on the first surface of the trench by using anisotropic etching method.

FIG. 13 is a cross-section representation of depositing the ozone-TEOS layer on the second silicon nitride layer and filling the trench.

FIG. 14 is a representation of substrate after using the chemical mechanical polishing method to remove the over deposited ozone-TEOS.

FIG. 15 is a representation of using the method of the present invention for filling of the shallow trench isolation.

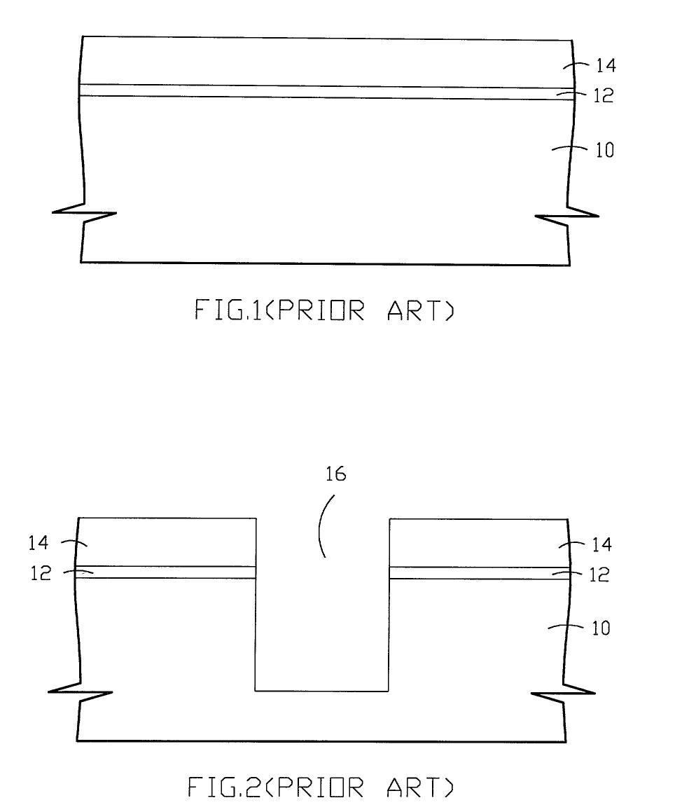

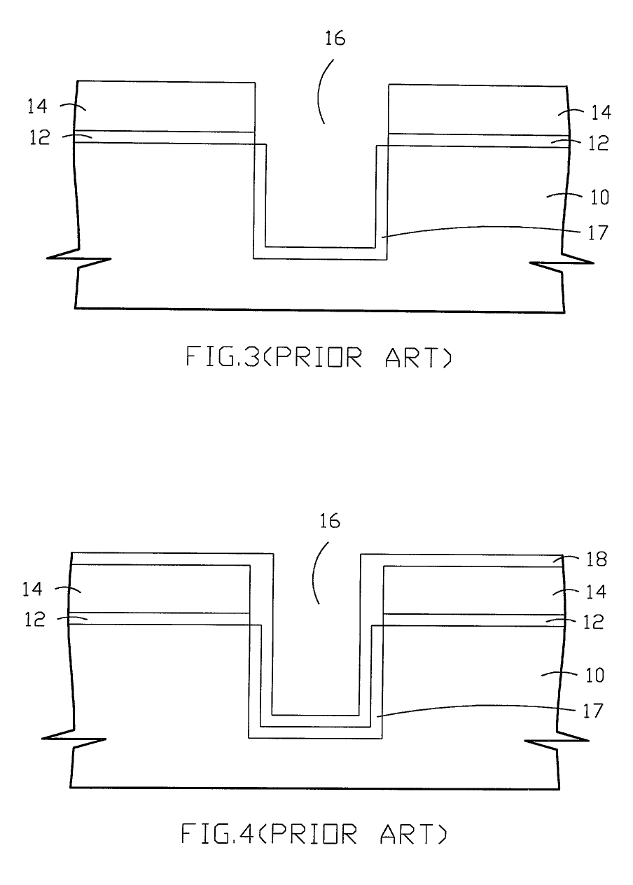

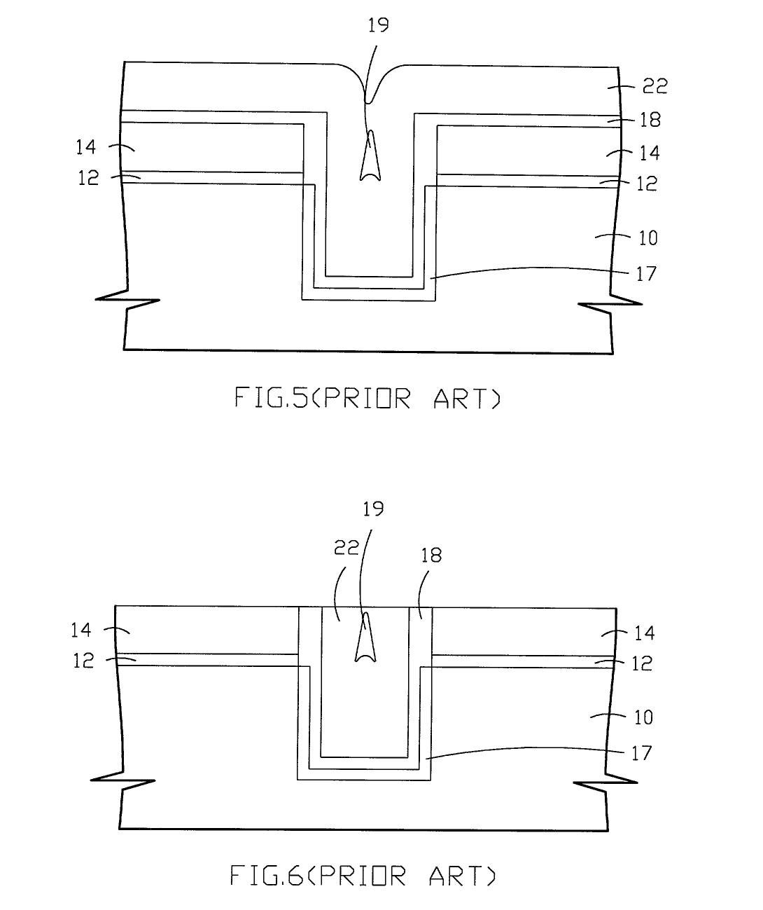

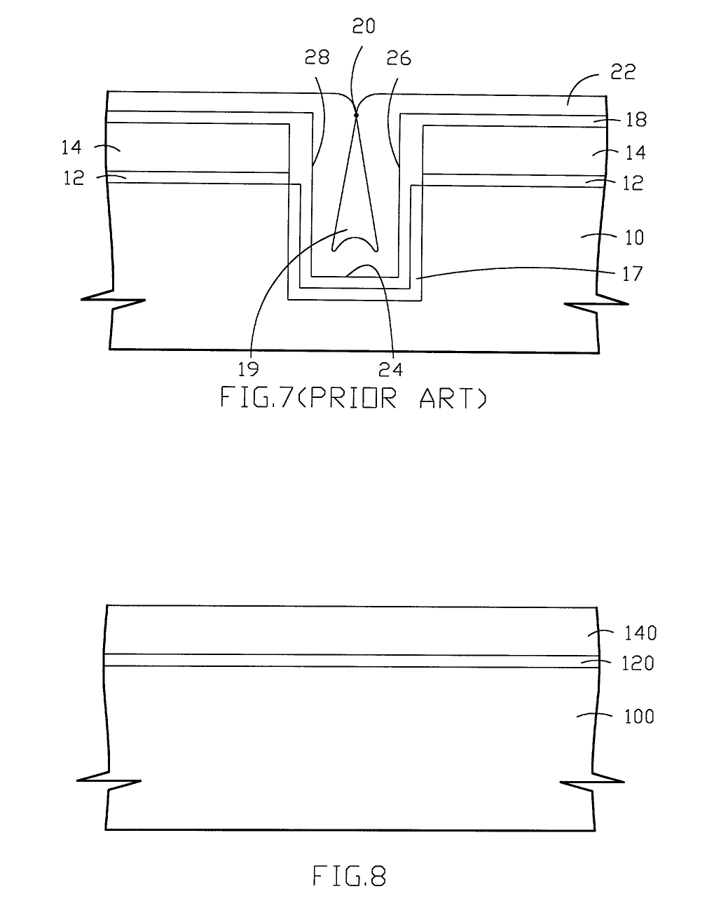

### DESCRIPTION OF THE PREFERRED EMBODIMENT

The foregoing aspects and many of the attendant advantages of this invention will become more readily appreciated as the same becomes better understood by reference to the following detailed description, when taken in conjunction with the accompanying drawings, wherein:

Referring to FIG. 8, there is shown a substrate which comprises a semiconductor substrate 100, a pad oxide layer 120 and the first silicon nitride layer 140. The material of the semiconductor substrate 100 is monocrystalline silicon. Shallow trench isolation regions are to be formed in the substrate to isolate active areas of the integrated circuit device from one another. A layer of pad oxide layer 120 is grown on the surface of the semiconductor substrate 100 and the material of the pad oxide layer is silicon dioxide in usual. The thickness of the pad oxide layer is about 100 to 120 angstroms and the thickness of the pad oxide layer is about 110 angstroms at present. Then the first silicon nitride layer 140 is deposited over the pad oxide layer 120. The thickness of the first silicon nitride layer 140 is about 1300 to 1700 angstroms and the thickness of the silicon nitride layer 140 is about 1500 angstroms at present.

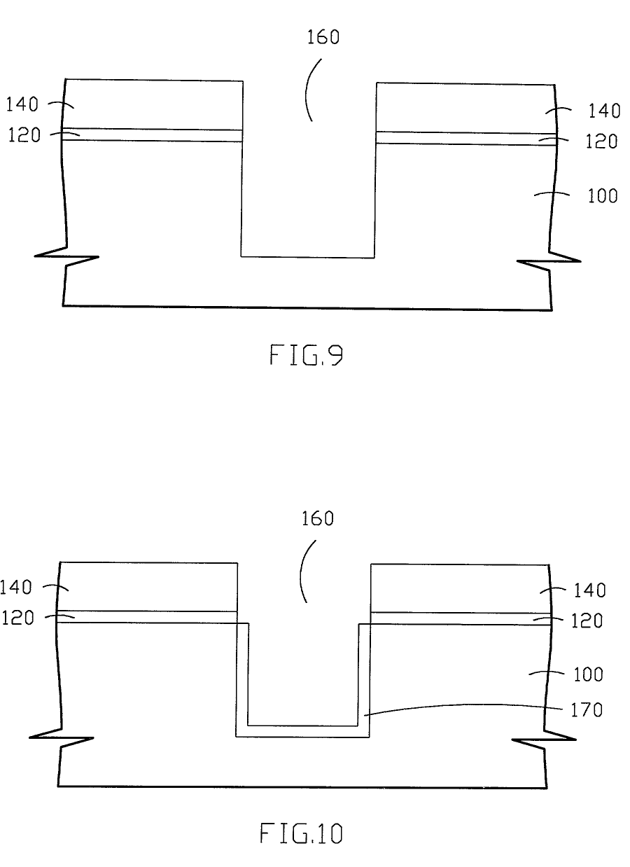

Referring to FIG. 9, a shallow trench is etched into the substrate using conventional photolithography and etching techniques. The shallow trenches 160 may be as small as 0.10 to 0.24 microns in width and are etched to a depth of between about 3000 and 4000 angstroms. A thermal oxide layer 170 is grown on the sidewalls of the trench 160 to a thickness of about 150 to 210 angstroms, as depicted in FIG. 10. This thermal oxide layer 170 provides a good sidewall isolation. Then the trench 160 is to be filled with a dielectric material. The trench 160 will be filled with ozone-TEOS. First, an underlayer is to be deposited within the trenches to eliminate surface sensitivity and to eliminate the deleterious effects of the thermal oxide underlayer on ozone-TEOS deposition and wet etch rates.

Referring to FIG. 11, the second silicon nitride layer 180 is deposited on the thermal oxide layer 17 and the first silicon nitride layer 140. A layer of plasma-enhanced silane oxide SiH₄ 180 is deposited by plasma enhanced chemical vapor deposition (PECVD) over the surface of the substrate and within the trenches 160. Then nitrogen is implanted to the plasma-enhanced silane oxide layer by using plasma treatment and the plasma-enhanced silane oxide become the second silicon nitride layer 180. The second silicon nitride layer 180 can eliminate surface sensitivity and to eliminate the deleterious effects of the thermal oxide underlayer on ozone-TEOS deposition and wet etch rates. The thickness of the second silicon nitride layer 180 is about 90 to 150 angstroms.

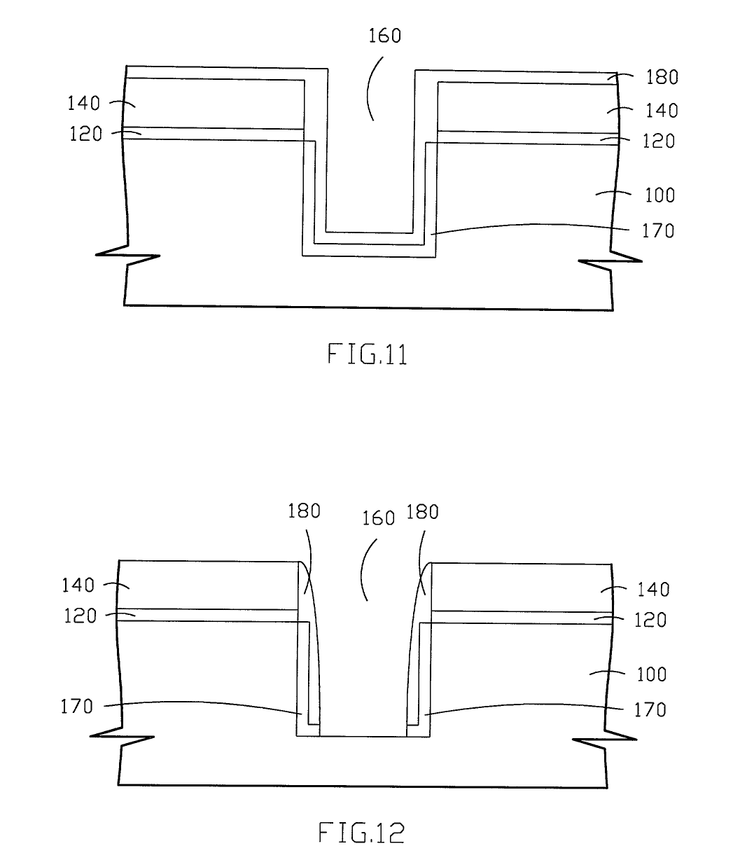

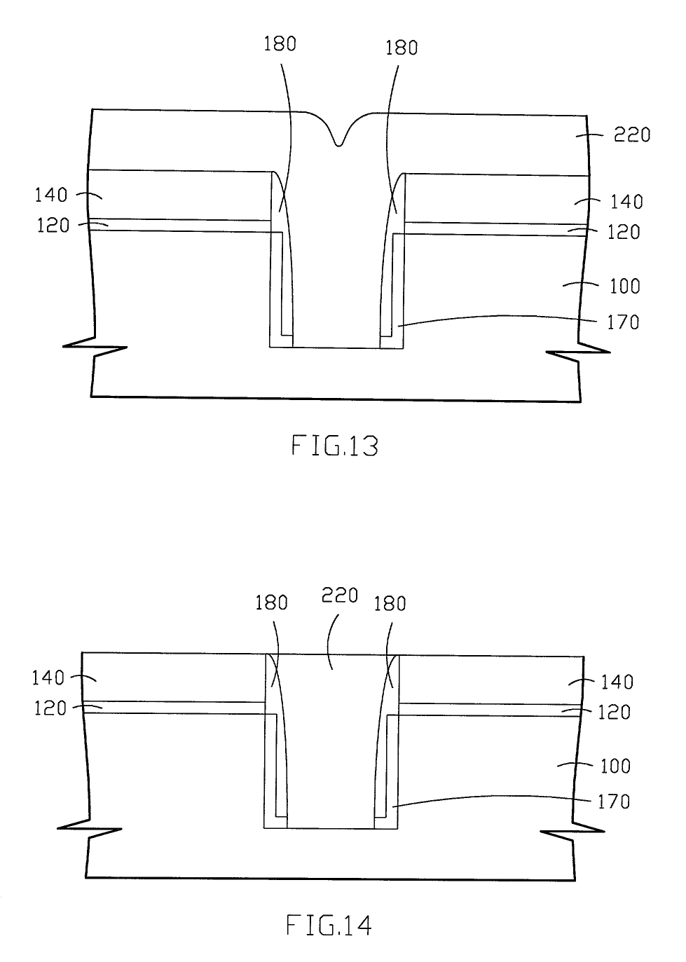

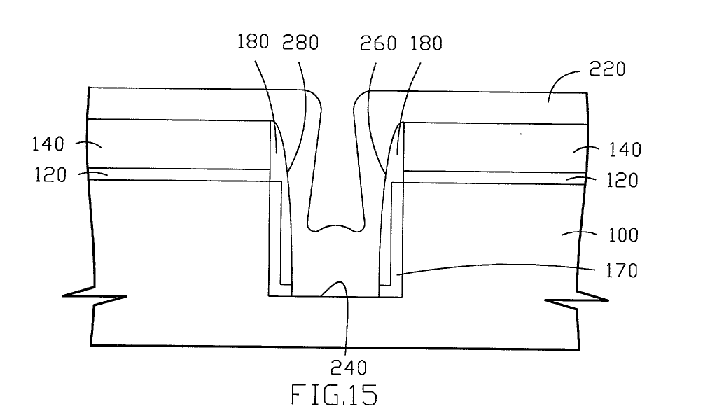

Referring to FIG. 12, we use the anisotropic etching method to remove the thermal oxide layer 170 and the second silicon nitride layer 180 from the first surface 240 of the trench 160, and to make the semiconductor substrate 100 be shown on the first surface 240 of the trench 160. The bottom of the trench 160 is the first surface 240 of the trench and the sidewalls of the trench 160 comprises the second surface 260 and the third surface 280 of the trench 160. At present, we use reactive ion etching method to be the anisotropic etching method. Referring to FIG. 13, the ozone-TEOS layer 220 is deposited on the second silicon nitride layer 180 and is filled of the trench 160 by using the subatmospheric chemical vapor deposition method. Referring to FIG. 14, the ozone-TEOS 220 which is over deposition is removed by using a polishing way. At present, the polishing way is chemical mechanical polishing (CMP). When we polish to the first silicon nitride layer, we stop the chemical mechanical polishing process and end the gap filling of shallow trench isolation process.

After finishing the deposition ozone-TEOS process and before proceeding chemical mechanical polishing process, we form an oxide layer on the contacting surface between the ozone-TEOS layer and the semiconductor substrate to increase the structure strength of the ozone-TEOS layer on the first surface of the trench and to remove the impurities which are in the contacting surface between the ozone-TEOS layer and the semiconductor substrate. If the oxide layer is formed on the contacting surface, the thickness of the oxide layer is about 90 to 110 angstroms.

In the traditional technologies, we can find that the ozone-TEOS reaction selective ratio of silicon to silicon nitride is about 1:5. In other words, the velocity of depositing ozone-TEOS on the silicon material is five times than the velocity of depositing ozone-TEOS on the silicon nitride material. We can use this technology to solve the void defects produced inside the filled material of the trench when we deposit the ozone-TEOS layer.

When we use the traditional technology to fill of shallow trench isolation by using ozone-TEOS, the deposition velocity of ozone-TEOS in the first surface 24, the second surface 26 and the third surface 28 of the trench are the same because the material in the first surface, the second surface, and the third surface of the trench is silicon nitride.

Although specific embodiments have been illustrated and described, it will be obvious to those skilled in the art that various modifications may be made without departing from what is intended to be limited solely by the appended claims. This condition can easily make that when ozone-TEOS which is deposited on the second surface of the trench, and ozone-TEOS which is deposited on the third surface 28 of the trench are contact with each other and ozone-TEOS which is deposited on the first surface of the trench still not reach this contact point. The vapor of ozone-TEOS will not enter into the trench and will not be deposited on the first surface 24 of the trench continuously. The void defects 19 will be produced inside the ozone-TEOS layer 22 in the trench 16 and will be found hardly. Referring to the FIG. 15, the present invention removes the second silicon nitride layer and the thermal oxide layer from the first surface of the trench, and show the semiconductor substrate on the first surface of the trench by using the anisotropic etching method before depositing the ozone-TEOS layer. The anisotropic etching method is the reactive ion etching method at present. When we start to deposit the ozone-TEOS layer, the velocity of depositing the ozone-TEOS layer on the first surface of the trench is five times than the velocity of depositing the ozone-TEOS layer on the second surface of the trench by using the velocity of depositing the ozone-TEOS layer on the semiconductor substrate to be five times than the velocity of depositing the ozone-TEOS layer on the silicon nitride layer. The velocity of depositing the ozone-TEOS layer on the second surface of the trench and the velocity of depositing the ozone-TEOS layer on the third surface of the trench are the same. This condition makes the way of filling trench from the bottom to the top of the trench. This filling way can avoid the void defects to be produced when ozone-TEOS which is deposited on the second surface of the trench, and ozone-TEOS which is deposited on the third surface 28 of the trench are contact with each other and ozone-TEOS which is deposited on the first surface of the trench still not reach this contact point. After finishing the gap filling of shallow trench isolation process, the void defects, which are not found easily inside the shallow trench isolation layer, will make the semiconductor elements to occur the leaking electric current conditions. When the volume of the semiconductor elements are decreased, the void defects are produced more easily inside the complete filled trench by using traditional technology to fill of the shallow trench isolation layer. Therefore, we must use the method of the present invention to increase the qualities of the semiconductor elements and to increase the density of elements on the semiconductor.

In accordance with the present invention, we use the difference between the velocity of depositing the ozone-TEOS layer on the silicon layer and the velocity of depositing the ozone-TEOS layer on the silicon nitride layer to remove the second silicon nitride layer and the thermal oxide layer from the first surface of the trench and to show the semiconductor substrate on the first surface of the trench by using anisotropic etching method before depositing the ozone-TEOS layer in the gap filling of shallow trench isolation process. The velocity of depositing the ozone-TEOS layer on the first surface of the trench is higher than the velocity of depositing the ozone-TEOS layer on the second or the third surface of the trench is higher in the depositing ozone-TEOS process. The way of filling trench is from the bottom to the top of the trench and can avoid the void defects, which are produced inside the filled layer and are found hardly to affect the qualities of the semiconductor elements, after finishing the filling process. The present invention can also make the volume of the semiconductor elements be decreased successfully and increase the density of elements in the semiconductor.

Although specific embodiments have been illustrated and described, it will be obvious to those skilled in the art that various modifications may be made without departing from what is intended to be limited solely by the appended claims.

What is claimed is:

1. A method for filling of a shallow trench isolation, said method comprises:
providing a wafer which comprises a semiconductor substrate;
forming a pad oxide layer on said semiconductor substrate;
forming a first silicon nitride layer on said pad oxide layer;
etching part of said first silicon nitride layer, said pad oxide layer, and said semiconductor substrate to form a trench;
forming a thermal oxide layer on a surface of said trench;
forming a second silicon nitride layer on said thermal oxide layer and said first silicon nitride layer;
anisotropic etching said second silicon nitride layer and said thermal oxide layer until showing said semiconductor substrate; and
forming a ozone-TEOS layer inside said trench.

2. The method according to claim 1, wherein said anisotropic etching method is a reactive ion etching method.

3. A method for filling of a shallow trench isolation, said method comprises:
providing a wafer which comprises a semiconductor substrate;
forming a pad oxide layer on said semiconductor substrate;
forming a first silicon nitride layer on said pad oxide layer;
etching part of said first silicon nitride layer, said pad oxide layer, and said semiconductor substrate to form a trench;
forming a thermal oxide layer on a surface of said trench;
forming a second silicon nitride layer on said thermal oxide layer and said first silicon nitride layer;
etching said second silicon nitride layer and said thermal oxide layer until showing said semiconductor substrate by using a reactive ion etching;
forming a ozone-TEOS layer inside said trench,
forming a oxide layer on a contacting surface which is located between said ozone-TEOS layer and said semiconductor substrate and on said bottom of said trench; and
polishing said ozone-TEOS layer until showing said first silicon nitride layer.

4. The method according to claim 3, wherein a width of said trench is about 0.10 to 0.24 microns.

5. The method according to claim 3, wherein a depth of said trench is about 3000 to 4000 angstroms.

6. The method according to claim 3, wherein said polishing method is a chemical mechanical polishing method.

7. The method according to claim 3, wherein a thickness of said oxide layer is about 90 to 110 angstroms.
